(19) United States
(12) Patent Application Publication
(10) Pub. No.: US 2011/0247684 A1
(43) Pub. Date: Oct. 13, 2011

(54) SOLAR CELL

(75) Inventors: HSIN-FEI HUANG, Chu-Nan (TW); KUO-FENG CHIANG, Chu-Nan (TW); ZHENG-JAY HUANG, Chu-Nan (TW)

(73) Assignee: FOXSEMICON INTEGRATED TECHNOLOGY, INC., Chu-Nan (TW)

(21) Appl. No.: 12/790,862

(22) Filed: May 31, 2010

(30) Foreign Application Priority Data
Apr. 12, 2010 (TW) 99111306

(51) Int. Cl. H01L 31/00

(52) U.S. Cl. 136/256

(57) ABSTRACT

A solar cell includes a base, a substrate, a number of solar chips and a light pervious cover. The substrate is received in the base, the solar chips are electrically mounted on the substrate. The light pervious cover covers the solar chips in the base. The light pervious cover includes a number of light converging portions corresponding to the solar chips and a number of extending portions aligned with the respective light converging portions. Each extending portion is engaged with a corresponding solar chip.

### BACKGROUND

1. Technical Field

The present disclosure relates to a solar cell.

2. Description of Related Art

Currently, converging lenses are employed in solar cells for enhancing optical-electrical converting efficiency. A solar cell typically includes a number of solar chips and a number of converging lenses corresponding to the solar chips. The solar chips are usually arranged in a matrix on a substrate, and each converging lens is aligned with a corresponding solar chip. However, it is difficult to align each converging lens to a corresponding solar chip. If a converging lens is misaligned with the corresponding solar chip, the optical-electrical converting efficiency of the solar chip may be reduced.

Therefore, what is needed is a solar cell addressing the above-mentioned problems.

### BRIEF DESCRIPTION OF THE DRAWINGS

The components of the drawings are not necessarily drawn to scale, the emphasis instead being placed upon clearly illustrating the principles of the embodiments of the solar cell. Moreover, in the drawings, like reference numerals designate corresponding parts throughout several views.

FIG. 1 is an exploded, isometric view of a solar cell according to an exemplary embodiment of the present disclosure.

FIG. 2 is similar to FIG. 1, but showing the solar cell viewed from a different aspect.

FIG. 3 is an assembled view of the solar cell of FIG. 1.

FIG. 4 is a cross sectional view of taking along IV-IV of the solar cell of FIG. 3.

### DETAILED DESCRIPTION

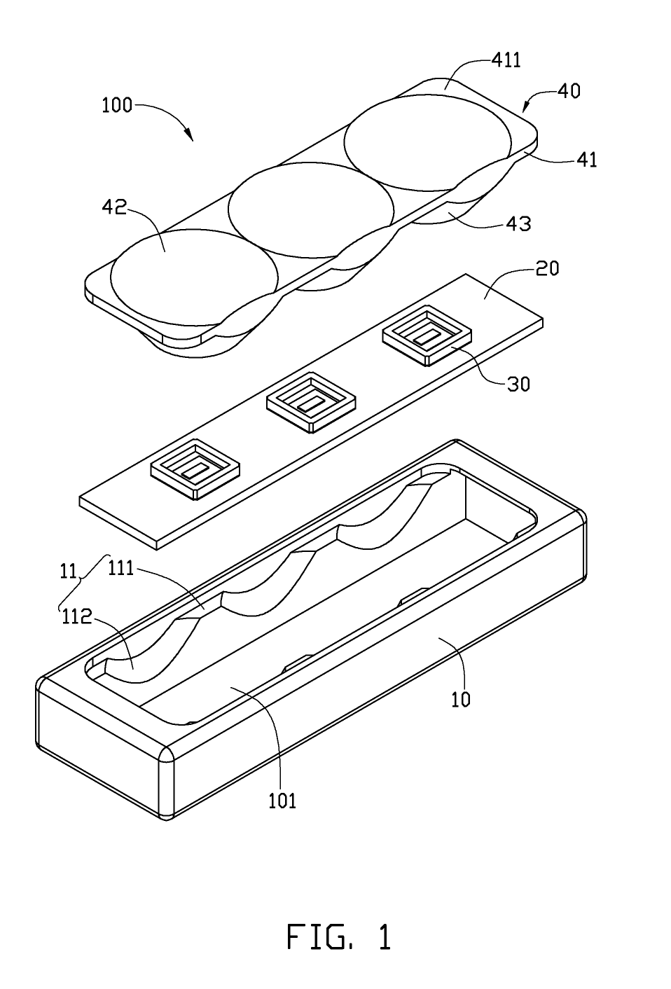

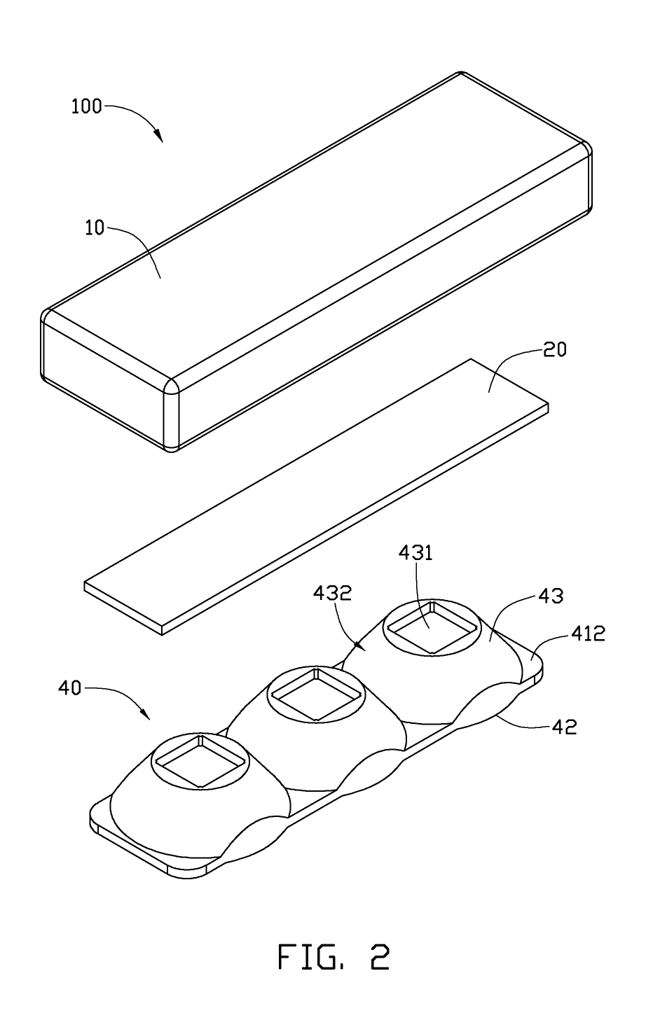

Referring to FIG. 1 and FIG. 2, a solar cell 100, according to an exemplary embodiment, is shown. The solar cell 100 includes a base 10, a substrate 20 received in the base 10, a number of solar chips 30 electrically mounted on the substrate 20 and a light pervious cover 40 covering the solar chips 30 in the base 10.

The base 10 defines a receiving space 101 configured for receiving the substrate 20 therein, the substrate 20 is positioned on the bottom surface of the receiving space 101. The base 10 includes a supporting portion 11 formed on the side surface of the receiving space 101. In this embodiment, the receiving space 101 is rectangular, and the supporting portion 11 is formed on opposite side surfaces of the receiving space 101. The supporting portion 11 includes a number of flat parts 111 and a number of concave parts 112 in between the respective flat parts 111. The flat parts 111 are spaced apart by the concave parts 112 and vice versa.

The substrate 20 is configured for fixing the solar chips 30 on the surface thereof. The substrate 20 includes a circuit system therein (not shown). The circuit system is electrically connected to the solar chips 30 for conducting current form the solar chips 30.

The solar chips 30 are configured for optical-electrical converting. The solar chips 30 can be selected from a type of silicon solar chip, dye solar chip, polymer solar chip, or other types. The current converted by the solar chips 30 can be conducted to an electronic device through the circuit of the substrate 20

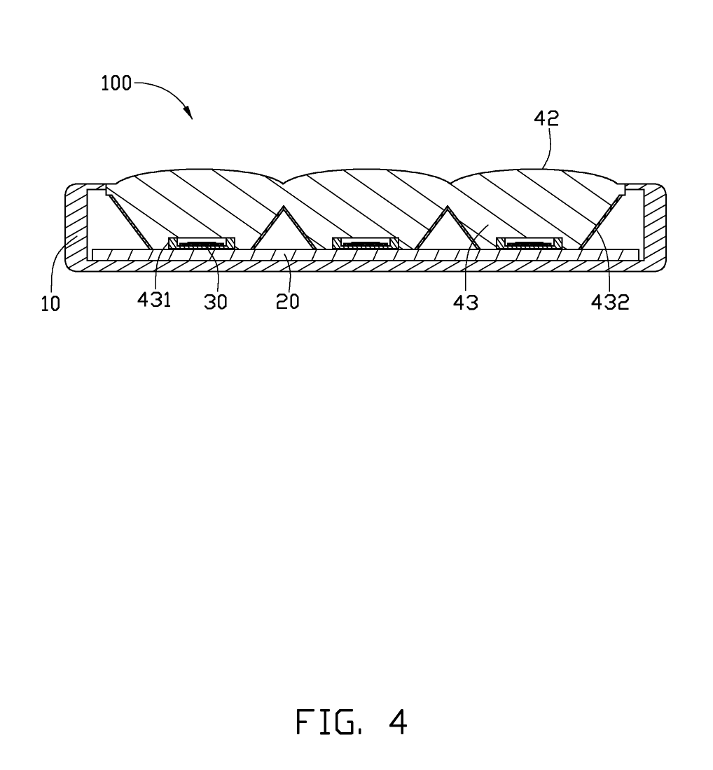

The light pervious cover 40 includes a plate portion 41, a number of light converging portions 42 arranged on the plate portion 41 and a number of extending portions 43 corresponding to the light converging portions 42. The plate portion 41 includes a first surface 411 and a second surface 412 opposite to the first surface 411. The light converging portions 42 are protruded from the first surface 411, and the light converging portions 42 have convex surfaces for converging light (see FIG. 4). Each extending portion 43 corresponds to a light converging portion 42 and protrudes a distance from the second surface 412. The side surface of the extending portions 43 and the surface of the concave parts 112 match up with each other. The free end of each extending portion 43 defines an aligning recess 431, the aligning recess 431 are shaped and sized corresponding to the solar chips 30. In this embodiment, the extending portion 43 is frustum shaped, and the narrower end of the extending portion 43 is far away from the second surface 412. Each extending portion 43 further includes a reflecting film 432 (see FIG. 4) formed on a peripheral side surface thereof, the reflecting film 432 is configured for avoiding the incidental light from leaking out through the side surface of the extending portion 43.

Each light converging portion 42 can be integrated with a corresponding extending portion 43, the integrated light converging portion 42 and the extending portion 43 pass through the plate portion 41 and fixedly connected to the plate portion 41. The light converging portion 42 and the extending portion 43 are comprised of a same transparent material. Alternatively, the plate portion 41, the light converging portion 42, and the extending portion 43 can also be integrated with each other to form the unitary light pervious cover 40, and all made from transparent material. In this embodiment, the plate portion 41, the light converging portion 42, and the extending portion 43 are integrated with each other

In this embodiment, there are three each of the solar chips 30, the light converging portions 42, and the extending portions 43. And the solar cell 100 can be used for providing electrical power for portable electronic devices, such as mobile phones, digital cameras, Global Position System (GPS) devices and so on. The number of the solar chips 30, the light converging portions 42 and the extending portions 43 can be changed according to different situations or circumstances.

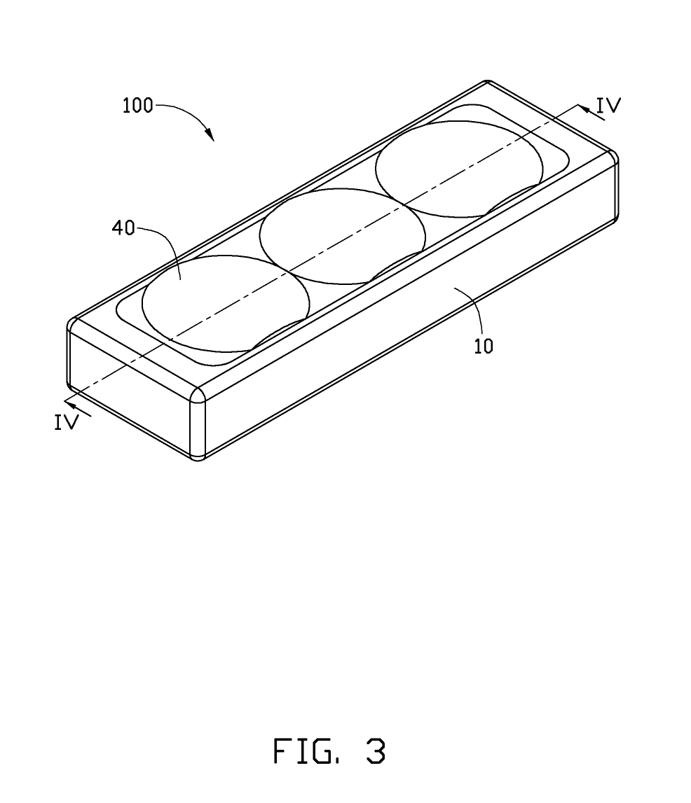

Referring to FIG. 3 and FIG. 4, in assembly, the solar chips 30 are attached to the surface of the substrate 20, then the substrate 20 and the solar chips 30 are placed into the receiving space 101 of the base 10. The light pervious cover 40 covers the receiving space 101 of the base 10 as well as the substrate 20 and the solar chips 30. The light pervious cover 40 is supported on the supporting portion 11 (see in FIG. 1), in detail, the second surface 412 of the plate portion 41 is supported on the flat parts 111, and the side surface of extending portions 13 are supported on the corresponding concave parts 112. Each solar chip 30 is matched with a corresponding aligning recess 431, and each light converging portion 42 is aligned with a corresponding solar chip 30 by fittingly engaging the solar chip 30 in the corresponding aligning recess 431. Therefore, it is easy to align each of the light converging portions 42 with a corresponding solar chip 30.

In use, incidental light passes through the light converging portions 42 and the extruding portions 43 in sequence, and finally projects on the solar chips 30. The incidental light is converged when passing through the light converging portion 42, and most of the incidental light can be projected on the solar chips 30 because of the reflecting films 432. Therefore, the optical-electrical converting efficiency of the solar chips 30 can be enhanced.

It is believed that the present embodiments and their advantages will be understood from the foregoing description, and it will be apparent that various changes may be made thereto without departing from the spirit and scope of the disclosure or sacrificing all of its material advantages, the examples presented within this document described merely being preferred or exemplary embodiments of the disclosure.

What is claimed is:

1. A solar cell, comprising:
a base;
a substrate received in the base;
a plurality of solar chips electrically mounted on the substrate; and
a light pervious cover covering the solar chips in the base;
wherein the light pervious cover comprises a plurality of light converging portions spatially corresponding to the solar chips and a plurality of extending portions aligned with the respective light converging portions, each extending portion engaged with a corresponding solar chip.

2. The solar cell of claim 1, wherein the base defines a receiving space configured for receiving the substrate therein, the substrate is positioned on the bottom surface of the base in the receiving space.

3. The solar cell of claim 2, wherein the base comprises a supporting portion in the receiving space, the light pervious cover is supported on the supporting portion.

4. The solar cell of claim 3, wherein the light pervious cover comprises a plate portion, the plate portion comprises a first surface and a second surface opposite to the first surface, the light converging portions protruding from the first surface, the extending portion protruding from the second surface.

5. The solar cell of claim 4, wherein the supporting portion comprises a plurality of flat parts and a number of spaced concave parts, the second surface of the plate portion is supported on the flat parts, the side surface of the extending portions are supported on the concave parts.

6. The solar cell of claim 5, wherein the light converging portions, the corresponding extending portions, and the plate portion cooperatively forms the unitary light pervious cover.

7. The solar cell of claim 5, wherein the plate portion, the light converging portions and the extending portions are comprised of a same material.

8. The solar cell of claim 1, wherein the free end of each extending portion defines an aligning recess, the aligning recesses are shaped and sized corresponding to the solar chips, and each solar chip is fittingly engaged in a corresponding aligning recess.

9. The solar cell of claim 1, wherein the solar chips are selected from a group consisting of silicon solar chips, dye solar chips and polymer solar chips.

10. The solar cell of claim 1, wherein each extending portion includes a reflecting film formed on a peripheral side surface thereof.

11. A solar cell, comprising:
a substrate;
a plurality of solar chips electrically mounted on the substrate; and
a light pervious cover attached on the substrate, the light pervious cover including a plurality of light converging portions, each light converging portion having a first outwardly curved surface, an opposite second flat surface, and a recess defined in the second surface, each light converging portion tapering from the first surface to the second surface, the solar chips received in the respective recesses.
